(19) United States
(12) Patent Application Publication
(10) Pub. No.: US 2019/0280186 A1
(43) Pub. Date: Sep. 12, 2019

(54) MAGNETIC MEMORY

(71) Applicant: TOSHIBA MEMORY CORPORATION, Tokyo (JP)

(72) Inventors: Saori KASHIWADA, Yokohama Kanagawa (JP); Junichi ITO, Yokohama Kanagawa (JP); Chikayoshi KAMATA, Kawasaki Kanagawa (JP); Megumi YAKABE, Kawasaki Kanagawa (JP)

(73) Assignee: TOSHIBA MEMORY CORPORATION, Tokyo (JP)

(21) Appl. No.: 16/119,060

(22) Filed: Aug. 31, 2018

(30) Foreign Application Priority Data
Mar. 12, 2018 (JP) 2018-044525

(51) Int. Cl. H01L 43/02; H01L 27/22; H01L 43/12

(52) U.S. Cl. CPC H01L 43/02; H01L 43/10; H01L 43/12; H01L 27/228

(57) ABSTRACT

A magnetic memory according to an embodiment includes: an electrode including a lower face, an upper face opposed to the lower face, and a side face different from the lower and upper faces; a magnetoresistive element disposed on the upper face of the electrode, including a multilayer structure including a first magnetic layer disposed above the upper face of the electrode, a second magnetic layer disposed between the upper face of the electrode and the first magnetic layer, and a nonmagnetic layer disposed between the first magnetic layer and the second magnetic layer; a first insulating film disposed on the side face of the electrode; and a second insulating film including a first portion disposed on a side face of the multilayer structure of the magnetoresistive element, and a second portion, the first insulating film being disposed between the second portion and the side face of the electrode.

### CROSS REFERENCE TO RELATED APPLICATIONS

This application is based upon and claims the benefit of priority from the prior Japanese Patent Application No. 2018-044525, filed on Mar. 12, 2018, the entire contents of which are incorporated herein by reference.

### FIELD

Embodiments described herein relate generally to magnetic memories.

### BACKGROUND

Magnetic memories (hereinafter also referred to as MRAMs (Magnetic Random Access Memories)) generally have a magnetic tunnel junction (MTJ) element that serves as a storage element. The MTJ element is formed on an electrode disposed on a substrate. The MTJ element has a multilayer structure including a first magnetic layer disposed above the electrode, a second magnetic layer disposed between the first magnetic layer and the electrode, and a nonmagnetic layer (“tunnel barrier layer”) disposed between the first magnetic layer and the second magnetic layer.

In order to avoid the degradation of characteristics of the MTJ element, side faces of the MTJ element are covered by a protective film of an insulating material such as Si₃N₄. The protective film covers an upper face of the electrode except for a region where the MTJ element is disposed, and a n of a lower insulating film disposed on the substrate.

### BRIEF DESCRIPTION OF THE DRAWINGS

FIG. 1 is a cross-sectional view of a magnetic memory according to a first embodiment.

FIG. 2 is a cross-sectional view illustrating a method of manufacturing a magnetic memory according to a second embodiment.

FIGS. 3 to 14 are cross-sectional views illustrating a manufacturing process according to the second embodiment.

### DETAILED DESCRIPTION

Before embodiments of the present invention are described, how the present invention has been reached will be described.

A protective film of an insulating material such as Si₃N₄ is formed on side faces of an MTJ element, an upper face of an electrode other than a region where the MTJ element is formed, and an upper face of a lower insulating film disposed on a substrate. Both of the protective film and the lower insulating film are formed of a ceramic material, which is an insulating material. The ceramic materials are mainly bonded by ionic bonds, covalent bonds, or van der Waals bonds. The protective film may easily adhere to the upper face of the lower insulating film since the ceramic materials may easily form bonds at the interface.

However, the electrode and a part of the side faces of the MTJ element are mainly formed of a metal material. The metal materials are bonded by metal bonds. The protective film of a ceramic material thus is not easily bonded to the part of the side faces of the MTJ element and the upper face of the electrode since it is difficult to form bonds at the interface. Therefore, the protective film does not easily adhere to the part of the side faces of the MTJ element, and to the upper face of the electrode. Therefore, the characteristics of the MTJ element may degrade, and further the reliability of the magnetic memory may degrade.

A metal-ceramic reaction layer may be disposed between the metal material and the ceramic material in order to improve the degree of adhesion between the metal material and the ceramic material. However, the metal-ceramic reaction layer disposed on the side faces of the MTJ element may degrade characteristics of the MTJ element. The reason for this is that in the first place, the material of the protective film is chosen from those that are difficult to react with a material exposed on the side faces of the MTJ element so that no reaction such as oxidation is caused on the side faces of the MTJ element. Therefore, formation of the metal-ceramic reaction layer on the side faces of the MTJ element may cause a problem.

As the pitch of arranged MTJ elements decreases, the area in which the protective film is in contact with the lower insulating film decreases. Therefore, the area in which the protective film has good adhesion is decreased. On the other hand, as the pitch decreases, the area in which the protective film is in contact with the side faces of the MTJ element and the upper face of the electrode increases. Therefore, the area in which the protective film is difficult to adhere increases.

Thus, if the pitch of the arranged MTJ elements decreases, the adhesion of the protective film to the substrate degrades. This may increase the probability of the protective film coming off during the manufacture or the operation of the device. If the protective film comes off during the manufacture or the operation of the device, oxygen, water, or corrosive gases may enter the interface between the MTJ element and the protective film, and degrade the characteristics of the MTJ element. This in turn degrades the reliability of the magnetic memory. For example, if the pitch of the arranged MTJ elements is equal to 40 nm or less, the above-described problem becomes marked. If a sum of a length along a stacked direction of a multilayer structure of the MTJ element 10 and a thickness of the cap layer 20 is more than a half of the pitch of the arranged MTJ elements the above-described problem becomes marked.

The inventors of the present invention studied hard to obtain a magnetic memory that may solve the problem. Embodiments of such a magnetic memory will be described below.

A magnetic memory according to an embodiment includes: an electrode including a lower face, an upper face opposed to the lower face, and a side face that is different from the lower face and the upper face; a magnetoresistive element disposed on the upper face of the electrode, including a multilayer structure including a first magnetic layer disposed above the upper face of the electrode, a second magnetic layer disposed between the upper face of the electrode and the first magnetic layer, and a nonmagnetic layer disposed between the first magnetic layer and the second magnetic layer; a first insulating film disposed on the side face of the electrode; and a second insulating film including a first portion disposed on a side face of the multilayer structure of the magnetoresistive element, and a second portion, the first insulating film being disposed between the second portion and the side face of the electrode.

### First Embodiment

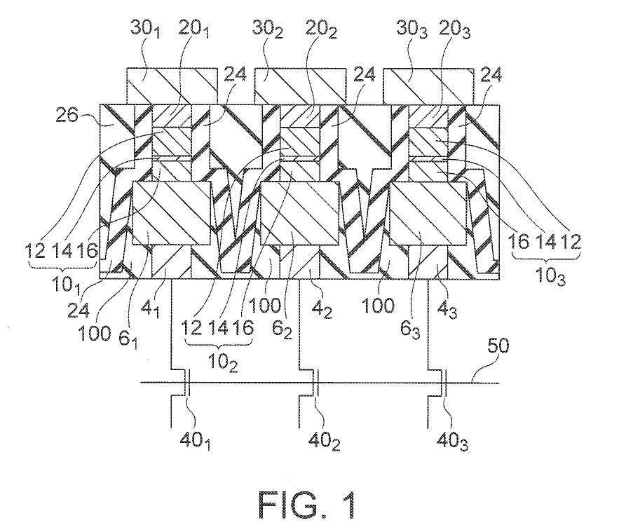

FIG. 1 shows a magnetic memory according to a first embodiment. The magnetic memory according to this embodiment includes a plurality of (three in FIG. 1) magnetoresistive elements, for example MTJ elements 10₁ to 10₃. Each MTJ element 10₁ (i=1, 2, 3) includes a magnetic layer (first magnetic layer) 12 disposed above an upper face of an electrode 6ᵢ, a magnetic layer (second magnetic layer) 16 disposed between the magnetic layer 12 and the electrode 6ᵢ, and a nonmagnetic layer (tunnel barrier layer) 14 disposed between the magnetic layer 12 and the magnetic layer 16. The diameter of the electrode 6ᵢ (i=1, 2, 3) is greater than the diameter of the MTJ element 10ᵢ. The diameter of the electrode 6ᵢ (i=1, 2, 3) and the diameter of the MTJ element 10ᵢ mean a maximum diameter in a plane that is perpendicular to the direction in which layers of the MTJ element 10ᵢ are stacked. The maximum diameter means a maximum value of a distance between arbitrarily selected two points on a circumference of the electrode 6ᵢ (i=1, 2, 3) or the MTJ element 10ᵢ when sectioned in the plane. Therefore, the cross-sectional area of the electrode 6ᵢ (i=1, 2, 3) that is parallel to the upper face of the electrode 6ᵢ is greater than the cross-sectional area of the MTJ element 10ᵢ that is parallel to the upper face of the electrode 6ᵢ. This means that the MTJ element 10ᵢ (i=1, 2, 3) is disposed on a part of the upper face of the electrode 6ᵢ.

A contact plug 4ᵢ that is electrically connected to a part of a lower face of each electrode 6ᵢ (i=1, 2, 3) is disposed to be electrically connected to one of a source terminal and a drain terminal of a selection transistor 40ᵢ for selecting a corresponding MTJ element 10₁. The state “A is electrically connected to B” herein means that A may be directly connected to B or that A may be indirectly connected to B via a conductive material. A gate of the selection transistor 40ᵢ (i=1, 2, 3) is electrically connected to a wiring 50.

A cap layer 20ᵢ is disposed on each MTJ element 10ᵢ (i=1, 2, 3). The MTJ element 10ᵢ (i=1, 2, 3) and the cap layer 20ᵢ are included in a multilayer structure disposed on a corresponding electrode 6ᵢ.

An insulating film 100 containing, for example, silicon oxide is disposed to cover side faces of each contact plug 4ᵢ (i=1, 2, 3), side faces of each electrode 6ᵢ, and a region of the lower face of each electrode 6ᵢ that is not connected to the contact plug 4ᵢ. In other words, the contact plugs 4₁ to 4₃ that are electrically connected to the selection transistors 40₁ to 40₃, respectively, are disposed within the insulating film 100, and the electrode 6ᵢ that is electrically connected to a corresponding contact plug 4ᵢ (i=1, 2, 3) is embedded in the insulating film 100. The thickness of the insulating film 100 disposed on each side face of the electrode 6ᵢ (i=1, 2, 3) increases from the upper face of the electrode 6ᵢ downward. Therefore, the cross-sectional area, which is parallel to the upper face of the electrode 6ᵢ, of the insulating film 100 disposed on the side face of the electrode 6ᵢ (i=1, 2, 3) increases from the upper face to the lower face of the electrode 6ᵢ (i=1, 2, 3). The insulating film 100 has a recessed portion between adjacent two MTJ elements.

A protective film 24 containing, for example, silicon nitride is disposed to cover side faces of the insulating film 100 and side faces of the multilayer structure including the MTJ element 10ᵢ (i=1, 2, 3) and the cap layer 20ᵢ. The protective film 24 also covers the region of the upper face of the electrode 6ᵢ (i=1, 2, 3) where the MTJ element 10₁ is not disposed. The protective film 24 is disposed along side faces and a bottom of each recessed portion of the insulating film 100 between adjacent two MTJ elements.

An interlayer insulating film 26 is disposed to cover side faces of the protective film 24 but not to cover the upper face of the protective film 24 and the upper face of the cap layer 20ᵢ (i=1, 2, 3). In FIG. 1, side faces of each of the electrode 6 (i=1, 2, 3) are covered with the insulating film 100, but are not in contact with the protective film 24. In an upper portion in side faces of each of the electrode 6 (i=1, 2, 3), the insulating film 100 may be removed and the portion in the side faces of each of the electrode 6 (i=1, 2, 3) may be in contact with the protective film 24.

A wiring 30ᵢ that is electrically connected to the upper face of the cap layer 20ᵢ (i=1, 2, 3) is disposed on the interlayer insulating film 26.

### (Write Method)

A method of writing data to each MTJ element 10ᵢ (i=1, 2, 3) in the magnetic memory according to the first embodiment including the above-described configuration will be described below. An example will be described, in which the magnetic layer 12 is a reference layer where a direction of magnetization is fixed, and the magnetic layer 16 is a storage layer where a direction of magnetization direction may be changed. If the magnetization direction of the magnetic layer 16 needs to be changed from antiparallel (opposite) to parallel (the same) relative to the magnetization direction of the magnetic layer 12, a write current is caused to flow from the magnetic layer 16 to the magnetic layer 12. As a result, spin-polarized electrons flow from the magnetic layer 12 to the magnetic layer 16 via the nonmagnetic layer 14, act on the magnetization of the magnetic layer 16, and change the magnetization direction of the magnetic layer 16 from antiparallel (opposite direction) to parallel (the same direction).

If the magnetization direction of the magnetic layer 16 needs to be changed from parallel to antiparallel relative to the magnetization direction of the magnetic layer 12, a write current is caused to flow from the magnetic layer 12 to the magnetic layer 16. As a result, spin-polarized electrons flow from the magnetic layer 16 to the magnetic layer 12 via the nonmagnetic layer 14. Electrons with spin that is in the same direction as the magnetization direction of the magnetic layer 12 pass through the magnetic layer 12. However, electrons with spin that is in the opposite direction to the magnetization direction of the magnetic layer 12 are reflected at the interface between the magnetic layer 12 and the nonmagnetic layer 14, and the reflected electrons act on the magnetization of the magnetic layer 16 to change the magnetization direction of the magnetic layer 16 from parallel to antiparallel.

If the magnetic layer 12 is a storage layer and the magnetic layer 16 is a reference layer, the direction of the current in each case is opposite to the above descriptions.

### (Read Method)

A method of reading data from the magnetic memory according to the first embodiment will be described, taking the case of the MTJ element 10₁ as an example. A voltage is applied to the wiring 50 to turn on the selection transistor 40ᵢ (i=1, 2, 3). Subsequently, a read current is caused to flow between one of the source terminal and the drain terminal of the selection transistor 40₁ and the wiring 30₁ via the MTJ element 10₁ to determine whether the magnetization direction of the magnetic layer 12 is parallel or antiparallel to the magnetic layer 16 in the MTJ element 10₁ based on the read current. As a result, data stored in the MTJ element 10₁ is read.

With the above-described configuration, the magnetic memory according to the first embodiment may have an increased contact area between the protective film 24 and the insulating film 100, which are bonded well with each other, even if the pitch of arranged MTJ elements is narrow. This may prevent the degradation of adhesion. As a result, the protective film may be prevented from coming off during the manufacture or the operation of the device. This in turn improves reliability of the magnetic memory.

Although each MTJ element 10₁ (i=1, 2, 3) is disposed on a region of the upper face of the electrode 6ᵢ in this embodiment, it may be disposed on the entire upper face of the electrode 6ᵢ. This means that the diameter of the electrode 6ᵢ (i=1, 2, 3) is the same as the diameter of the MTJ element 10ᵢ. In this case, the protective film 24 have a first portion arranged on each side face of the MTJ element 10ᵢ (i=1, 2, 3), and a second portion arranged on each side face of the electrode 6ᵢ, and the first portion and the second portion are continuously connected to each other.

Although the magnetoresistive elements 10₁ to 10₃ in this embodiment are magnetic tunnel junction (MTJ) elements in which the nonmagnetic layer 14 contains an insulating material, they may be giant magneto-resistance (GMR) elements in which the nonmagnetic layer 14 is a metal layer.

The magnetic layers 12 and 16 in this embodiment may be formed of CoFe or CoFeB. The magnetic layers 12 and 16 may have a synthetic multilayer structure.

The magnetic layers 12 and 16 in this embodiment may be magnetic layers of a material other than CoFeB or CoFe. The magnetic layers 12 and 16 in this embodiment may be formed a material having a magnetization that is perpendicular to the faces of the magnetic layers.

The magnetic layers 12 and 16 may be layers of a magnetic material such as a metallic element such as Ni, Fe, or C, an alloy such as Ni—Fe, Co—Fe, Co-Ni, or Co—Fe-Ni, an amorphous material such as (Co, Fe, Ni)—(Si, B), (Co, Fe, Ni)—(Si, B)—(P, Al, Mo, Nb, Mn), or Co—(Zr, Hf, Nb, Ta, Ti), or a Heusler alloy, or layers having a multilayer structure including layers of materials selected from the above-described materials. The expression (Co, Fe, Ni), for example, means that at least one of Co, Fe, and Ni is included. The Heusler alloys have a composition expressed as X₂YZ where X is Co, Y is at least one of V, Cr, Mn, and Fe, and Z is at least one of Al, Si, Ga, and Ge.

The magnetic layers 12 and 16 may also be layers of a magnetic material that is a perpendicular magnetization material such as an alloy including any of FePt, CoPt, CoCrPt, and (Co, Fe, Ni)—(Pt, Ir, Pd, Rh)—(Cr, Hf, Zr, Ti, Al, Ta, Nb), or a material (Co, Fe)/(Pt, Ir, Pd). The magnetic layers 12 and 16 may also have a multilayer structure including stacked layers of these perpendicular magnetization materials.

A nonmagnetic element such as silver (Ag), copper (Cu), gold (Au), aluminum (Al), ruthenium (Ru), osmium (Os), rhenium (Re), tantalum (Ta), boron (B), carbon (C), oxygen (O), nitrogen (N), palladium (Pd), platinum (Pt), zirconium (Zr), iridium (Ir), tungsten (W), molybdenum (Mo), or niobium (Nb) may be added to the above-described magnetic materials to adjust magnetic characteristics, and also physical characteristics such as crystallinity, mechanical characteristics, and chemical characteristics.

The nonmagnetic layer 14 may be formed of an insulating material such as aluminum oxide (Al₂O₃), silicon oxide (SiO₂), magnesium oxide (MgO), aluminum nitride (AlN), silicon nitride (SiN), bismuth oxide (Bi₂O₃), magnesium fluoride (MgF₂), calcium fluoride (CaF₂), strontium titanate (SrTiO₃), lanthanum aluminate (LaAlO₃), aluminum oxinitride (Al—N—O), or hafnium oxide (HfO), or a composite material including a combination of the insulating materials.

The nonmagnetic layer 14 may also be formed of at least one nonmagnetic metal such as copper, silver, gold, vanadium, chromium, or ruthenium, or at least one of the above materials containing an insulating material for current constriction.

### Second Embodiment

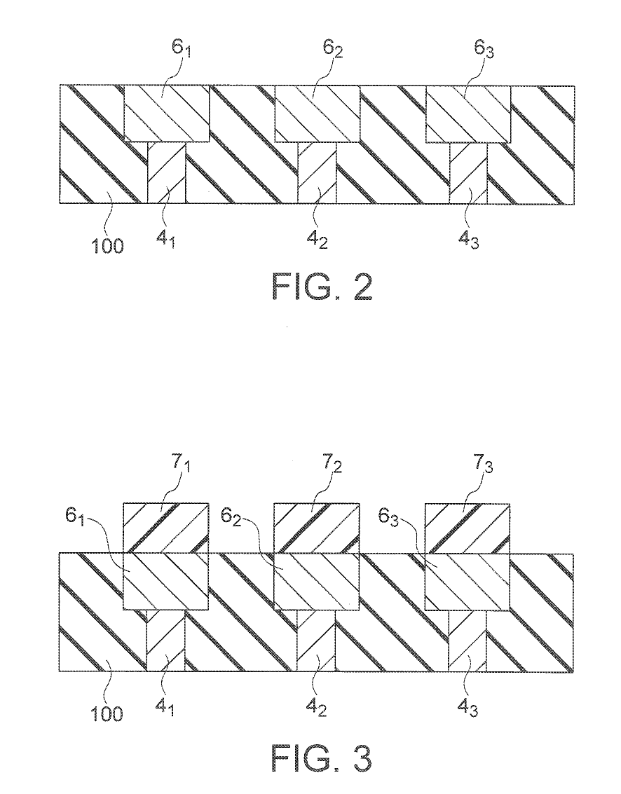

A method of manufacturing a magnetic memory according to a second embodiment will be described with reference to FIGS. 2 to 14. The magnetic memory according to the first embodiment shown in FIG. 1 is manufactured by this method.

As shown in FIG. 2, a first insulating layer containing silicon oxide, for example, is disposed on a semiconductor substrate on which three transistors that are not shown are formed. Openings each connecting to one of a source terminal and a drain terminal of one of the transistors are formed in the first insulating layer, and filled with a metal material to form contact plugs 4₁ to 4₃. Subsequently, a second insulating layer containing, for example, silicon oxide is disposed on the first insulating layer to cover the contact plugs 4₁ to 4₃. Openings connecting to the contact plugs 4₁ to 4₃ are then formed through the second insulating layer, and filled with a metal material to form electrodes (wirings) 6₁ to 6₃. Thereafter, surfaces of the electrodes 6₁ to 6₃ are smoothed by chemical mechanical polishing (CMP). The first insulating layer and the second insulating layer are included in an insulating film 100.

Next, a resist pattern 7ᵢ having the same size as each electrode 6ᵢ (i=1, 2, 3) is disposed on each electrode 6ᵢ (i=1, 2, 3), as shown in FIG. 3.

Subsequently, the insulating film 100 is etched at portions between the electrodes, using the resist patterns 7ᵢ (i=1, 2, 3) as masks, by reactive ion etching (RIE), for example, to form recessed portions 102. Each recessed portion 102 has a tapered shape, and the opening area of each recessed portion 102 is decreased from the top to the bottom (FIG. 4).

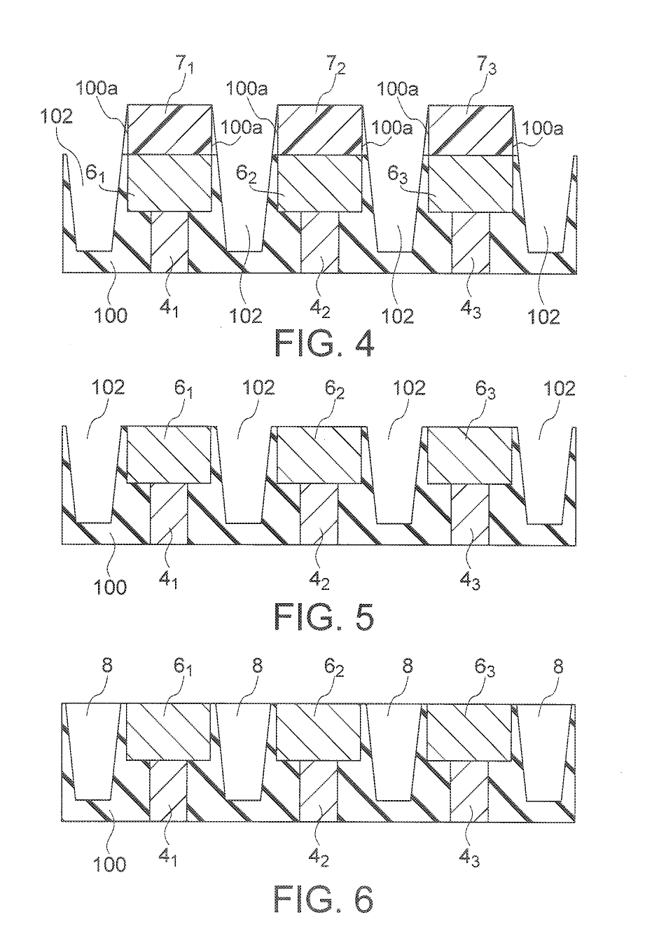

Etching conditions are selected in a manner that physical etching acts stronger than chemical etching, so that redeposition 100a caused by the etching of the insulating film 100 is attached to each side face of the electrode 6ᵢ (i=1, 2, 3). The redeposition 100a contains the same material as the insulating film 100 (FIG. 4). Thereafter, the resist patterns 7₁ to 7₃ are removed as shown in FIG. 5.

An embedded layer 8 is then formed to fill into each recessed portion 102, as shown in FIG. 6. The embedded layer 8 is removed in a later stage. Therefore, the material of the embedded layer 8 is selected from those having etching selectivity with the materials of the MTJ elements, the electrodes, and the insulating film 100, such as Si or C. Subsequently, the surface of the embedded layer 8 is smoothed by CMP.

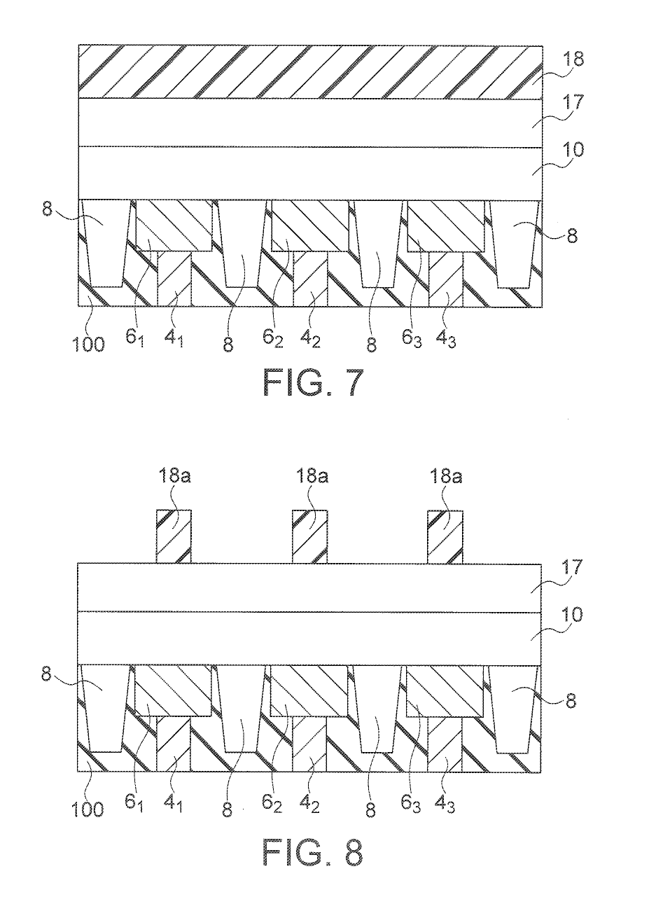

Next, as shown in FIG. 7, a material layer 10 for making the MTJ elements is formed to cover the electrodes 6₁ to 6₃ and the embedded layer 8. The material layer 10 includes a magnetic material layer (not shown) to become a reference layer for example, a nonmagnetic material layer (not shown) to become a tunnel barrier layer that is disposed on the magnetic material layer, a magnetic material layer (not shown) to become a storage layer for example, disposed on the nonmagnetic material layer, and a conductive material layer to become a cap layer disposed on the magnetic material layer. A hard mask layer 17 is disposed on the material layer 10, and a resist layer 18 is disposed on the hard mask layer 17. The hard mask layer 17 may be a layer of a conductive material (such as Ta, W, or TiN) or of an insulating material (such as B₄C, C, or Al₂O₃). In this embodiment, the hard mask layer 17 is a layer of a conductive material. In this case, the hard mask layer 17 may be used for the connection with wirings such as the wirings 30₁ to 30₃ shown in FIG. 1.

Next, as shown in FIG. 8, the resist layer 18 is patterned to have a shape of the MTJ elements using a photolithographic technique, to form resist patterns 18a.

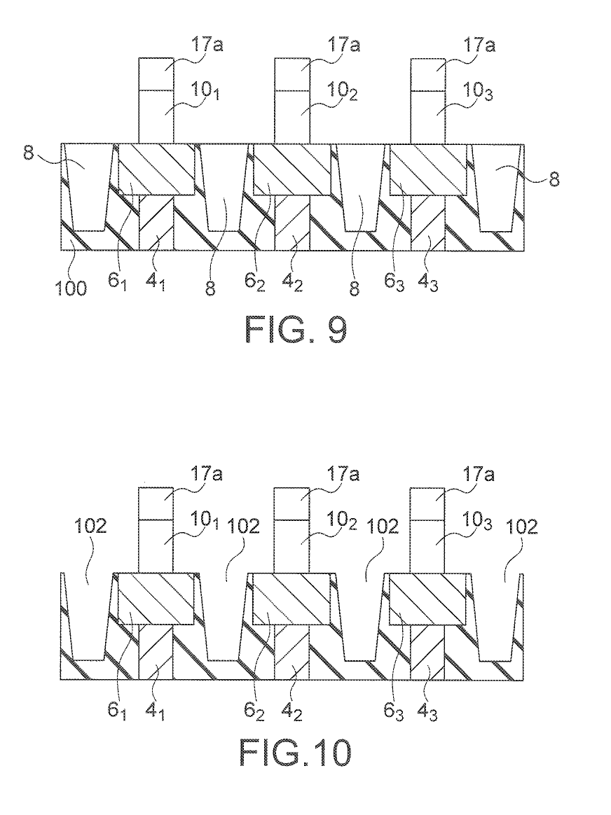

The hard mask layer 17 is then patterned by anisotropic etching (for example, RIE), using the resist patterns 18a as masks, to form hard mask patterns 17a. Subsequently, the material layer 10 is patterned by anisotropic etching, using the hard mask patterns 17a as masks. As a result, MTJ elements 10₁ to 10₃ are formed (FIG. 9).

Next, the embedded layer 8 is removed as shown in FIG. 10. After the embedded layer 8 is removed, the recessed portions 102 are exposed. If the embedded layer 8 is formed of Si, only the embedded layer 8 may be removed by RIE using SF₆ gas, for example, without etching the MTJ elements 10₁ to 10₃, the electrodes 6₁ to 6₃, and the insulating film 100. If the embedded layer 8 is formed of C, only the embedded layer 8 may be removed by RIE using O₂ gas, for example, without etching the MTJ elements 10₁ to 10₃, the electrodes 6₁ to 6₃, and the insulating film 100. Since the MTJ elements 10₁ to 10₃ are not formed using self-alignment technique with the electrodes 6₁ to 6₃, lower faces of the MTJ elements 10₁ to 10₃ may run off the edges of the side faces of the electrodes 6₁ to 6₃ to be overhung from the side faces of the electrodes 6₁ to 6₃. In this case, a part of the material of the embedded layer 8 may remain under overhanging regions of the lower faces.

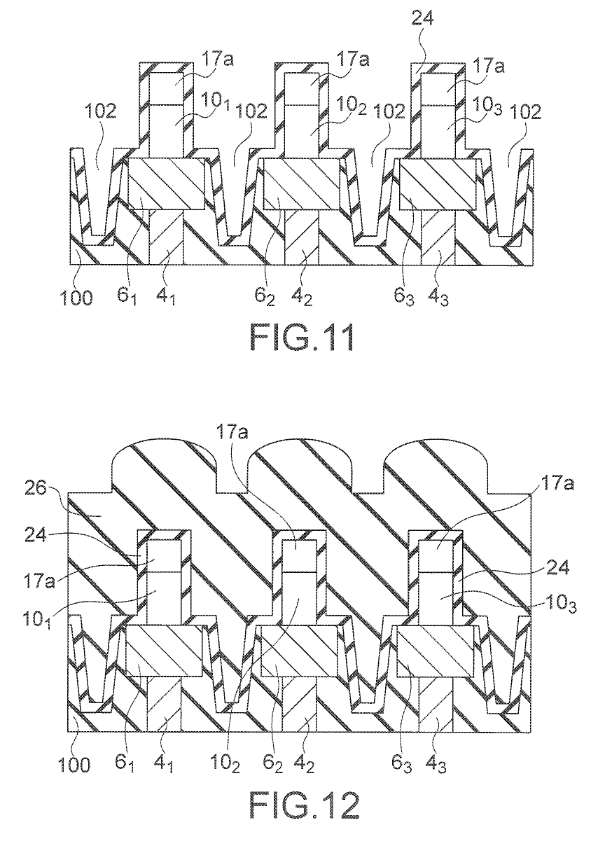

Next, as shown in FIG. 11, a protective film 24 is disposed on the entire face of the semiconductor substrate. The protective film 24 covers side faces of the electrodes 6₁ to 6₃, regions of the upper faces of the electrodes 6₁ to 6₃ where the corresponding MTJ elements 10₁ to 10₃ are not disposed, side faces of the MTJ element 10₁ to 10₃, and an upper face and side faces of the hard mask patterns 17a. The protective film 24 is also disposed on side faces and a bottom of each of the recessed portions 102 of the insulating film 100.

Next, as shown in FIG. 12, an interlayer insulating film 26 is disposed to cover the protective film 24. The interlayer insulating film 26 protrudes in regions above the MTJ elements 10₁ to 10₃.

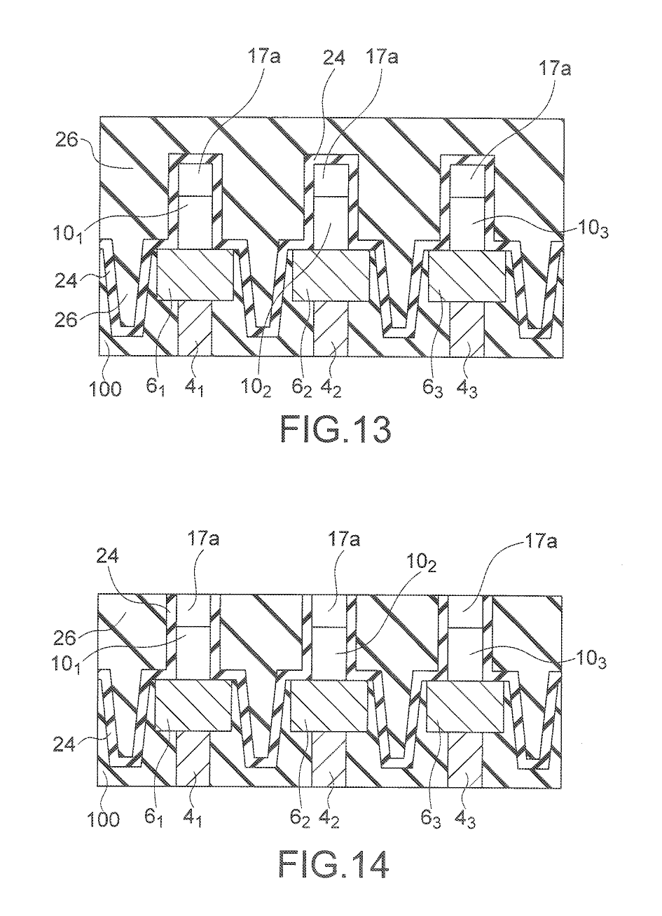

Subsequently, as shown in FIG. 13, the upper face of the interlayer insulating film 26 is smoothed by CMP without exposing the upper faces of the hard mask patterns 17a.

Next, as shown in FIG. 14, etch back of the interlayer insulating film 26 is performed using RIE, until the upper faces of the hard mask patterns 17a are exposed as shown in FIG. 14. The upper faces of the protective film 24 are also exposed at this time.

If the hard mask patterns 17a are formed of a conductive material, an upper wiring material layer is disposed to cover the upper faces of the hard mask patterns 17a, the upper face of the protective film 24, and the upper face of the interlayer insulating film 26. If the hard mask patterns 17a are formed of an insulating material, the hard mask patterns 17a are removed by selective etching, and then an upper wiring material layer that fills openings formed by the removal of the hard mask patterns 17a is disposed to cover the upper face and a part of the side faces of the protective film 24 and the upper face of the interlayer insulating film 26. Subsequently, the upper wiring material layer is patterned to form a wiring 30ᵢ connecting to the MTJ element 10₁ (i=1, 2, 3), thereby completing the magnetic memory shown in FIG. 1.

The magnetic memory manufactured according to the manufacturing method of the second embodiment may have an increased contact area between the protective film 24 and the insulating film 100, which a bonded well with each other, even if the pitch of arranged MTJ elements is narrow. This may prevent the degradation of adhesion. As a result, the protective film may be prevented from coming off during the manufacture or the operation of the device. This in turn improves reliability of the magnetic memory.

In the drawings of the first and second embodiments, the side faces of each of the MTJ elements 10ᵢ (i=1, 2, 3) and the electrodes 6ᵢ are perpendicular to an upper face of the semiconductor substrate. The side faces of each of the MTJ elements 10ᵢ (i=1, 2, 3) and the electrodes 6ᵢ may have forward tapered shapes depending on manufacturing conditions. In this case, an area and a diameter of the lower face of the MTJ element 10ᵢ (i=1, 2, 3) is greater than an area and a diameter of the upper face of the MTJ element 10ᵢ respectively, an area and a diameter of the lower face of the electrode 6ᵢ (i=1, 2, 3) is greater than an area and a diameter of the upper face of the electrode 6ᵢ respectively.

The side faces of each of the MTJ elements 10ᵢ (i=1, 2, 3) and the electrodes 6ᵢ may have inverse tapered shapes depending on manufacturing conditions. In this case, the area and the diameter of the lower face of the MTJ element 10ᵢ (i=1, 2, 3) is smaller than the area and the diameter of the upper face of the MTJ element 10ᵢ respectively, the area and the diameter of the lower face of the electrode 6ᵢ (i=1, 2, 3) is smaller than the area and the diameter of the upper face of the electrode 6ᵢ respectively.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A magnetic memory comprising:
an electrode including a lower face, an upper face opposed to the lower face, and a side face that is different from the lower face and the upper face;
a magnetoresistive element disposed on the upper face of the electrode, including a multilayer structure including a first magnetic layer disposed above the upper face of the electrode, a second magnetic layer disposed between the upper face of the electrode and the first magnetic layer, and a nonmagnetic layer disposed between the first magnetic layer and the second magnetic layer;
a first insulating film disposed on the side face of the electrode; and
a second insulating film including a first portion disposed on a side face of the multilayer structure of the magnetoresistive element, and a second portion, the first insulating film being disposed between the second portion and the side face of the electrode.

2. The magnetic memory according to claim 1, wherein the magnetoresistive element is disposed in a region of the upper face of the electrode, and the second insulating film further includes a third portion disposed in a further region that is other than the region on the upper face of the electrode, the third portion connecting the first portion and the second portion.

3. The magnetic memory according to claim 1, wherein the first insulating film includes a portion having a cross-sectional area in a plane parallel to the upper face of the electrode, the cross-sectional area of the portion increasing in a direction from the upper face to the lower face of the electrode.

4. The magnetic memory according to claim 1, wherein the first insulating film contains silicon oxide, and the second insulating film contains silicon nitride.

5. The magnetic memory according to claim 1, further comprising a wiring disposed above the magnetoresistive element and electrically connected to the first magnetic layer.

6. The magnetic memory according to claim 1, further comprising a conductor electrically connected to a region of the lower face of the electrode, the conductor including an upper face electrically connecting to the region, a lower face opposed to the upper face, and a side face that is different from the upper face and the lower face,
wherein the first insulating film is also disposed on the side face of the conductor.

7. The magnetic memory according to claim 6, further comprising a transistor including a source terminal and a drain terminal, one of which is electrically connected to the lower face of the conductor.

8. A magnetic memory comprising:
an electrode including a lower face, an upper face opposed to the lower face, and a side face that is different from the lower face and the upper face;
a magnetoresistive element disposed on the upper face of the electrode, including a multilayer structure including a first magnetic layer disposed above the upper face of the electrode, a second magnetic layer disposed between the upper face of the electrode and the first magnetic layer, and a nonmagnetic layer disposed between the first magnetic layer and the second magnetic layer;
a first insulating film disposed on the side face of the electrode; and
a second insulating film including a first portion disposed on a side face of the multilayer structure of the magnetoresistive element, and a second portion disposed on an opposite side of the first insulating film to the side face of the electrode.

9. The magnetic memory according to claim 8, wherein the magnetoresistive element is disposed in a region of the upper face of the electrode, and the second insulating film further includes a third portion disposed in a further region that is other than the region on the upper face of the electrode, the third portion connecting the first portion and the second portion.

10. The magnetic memory according to claim 8, wherein the first insulating film includes a portion having a cross-sectional area in a plane parallel to the upper face of the electrode, the cross-sectional area of the portion increasing in a direction from the upper face to the lower face of the electrode.

11. The magnetic memory according to claim 8, wherein the first insulating film contains silicon oxide, and the second insulating film contains silicon nitride.

12. The magnetic memory according to claim 8, further comprising a wiring disposed above the magnetoresistive element and electrically connected to the first magnetic layer.

13. The magnetic memory according to claim 8, further comprising a conductor electrically connected to a region of the lower face of the electrode, the conductor including an upper face electrically connecting to the region, a lower face opposed to the upper face, and a side face that is different from the upper face and the lower face,
wherein the first insulating film is also disposed on the side face of the conductor.

14. The magnetic memory according to claim 13, further comprising a transistor including a source terminal and a drain terminal, one of which is electrically connected to the lower face of the conductor.

15. A magnetic memory comprising:
an electrode including a lower face, an upper face opposed to the lower face, and a side face that is different from the lower face and the upper face;
a first insulating film, in which the lower face and the side face of the electrode are embedded, wherein a cross-sectional area, in a plane parallel to the upper face of the electrode, of a part of the first insulating film disposed on the side face of the electrode increases in direction from the upper face to the lower face of the electrode;
a magnetoresistive element disposed on the upper face of the electrode, including a multilayer structure including a first magnetic layer disposed above the upper face of the electrode, a second magnetic layer disposed between the upper face of the electrode and the first magnetic layer, and a nonmagnetic layer disposed between the first magnetic layer and the second magnetic layer; and
a second insulating film including a first portion disposed on a side face of the multilayer structure of the magnetoresistive element, and a second portion disposed on an opposite side of the first insulating film to the side face of the electrode.

16. The magnetic memory according to claim 15, wherein the magnetoresistive element is disposed in a region of the upper face of the electrode, and the second insulating film further includes a third portion disposed in a further region that is other than the region on the upper face of the electrode, the third portion connecting the first portion and the second portion.

17. The magnetic memory according to claim 15, wherein the first insulating film contains silicon oxide, and the second insulating film contains silicon nitride.

18. The magnetic memory according to claim 15, further comprising a wiring disposed above the magnetoresistive element and electrically connected to the first magnetic layer.

19. The magnetic memory according to claim 15, further comprising a conductor electrically connected to a region of the lower face of the electrode, the conductor including an upper face electrically connecting to the region, a lower face that is opposed to the upper face, and a side face that is different from the upper face and the lower face,
wherein the first insulating film is also disposed on the side face of the conductor.

20. The magnetic memory according to claim 19, further comprising a transistor including a source terminal and a drain terminal, one of which is electrically connected to the lower face of the conductor.
